(19) United States
(12) Patent Application Publication
(10) Pub. No.: US 2025/0277826 A1
(43) Pub. Date: Sep. 4, 2025

(54) SOURCE-AGNOSTIC TIME-DOMAIN DIRECTIONAL RELAY FOR POWER GRID

(71) Applicant: CLEMSON UNIVERSITY, CLEMSON, SC (US)

(72) Inventors: SUKUMAR BRAHMA, CLEMSON, SC (US); PRABIN ADHIKARI, CLEMSON, SC (US)

(21) Appl. No.: 19/053,885

(22) Filed: Feb. 14, 2025

Related U.S. Application Data
(60) Provisional application No. 63/559,243, filed on Feb. 29, 2024.

(51) Int. Cl. G01R 19/14; G01R 31/327; H02J 3/38; H02J 13/00

(52) U.S. Cl. CPC G01R 19/14; G01R 31/3278; H02J 3/38; H02J 13/00002

(57) ABSTRACT

The disclosure deals with system and methodology subject matter for source-agnostic time-domain directional relays for power grid applications, including system and methodology subject matter for Inverter based resources (IBRs) which are instrumental in facilitating the integration of renewable energy resources and storage into the power grid. IBRs exhibit unique fault characteristics significantly different from synchronous generators (SGs), dictated by their proprietary controls, posing challenges for the reliable operation of directional relays designed in phasor domain. This disclosure relates to a source-agnostic directional relay formulated in time domain, thus making any polarization unnecessary. It is immune to decaying dc offset and pre-fault currents, and applicable to transmission and distribution feeders with up to 100% IBR penetration. Its performance is superior to a numerical commercial relay in a hardware in the loop setup, and its chosen sampling rate of 24 or more samples per cycle (spc) makes it readily implementable in commercial numerical relays.

### PRIORITY CLAIM

The present application claims the benefit of priority of U.S. Provisional Patent Application No. 63/559,243, filed Feb. 29, 2024, titled Source-Agnostic Time-Domain Directional Relay For Power Grid, and the contents of which is fully incorporated herein by reference for all purposes.

### STATEMENT REGARDING FEDERALLY SPONSORED RESEARCH OR DEVELOPMENT

This invention was made with government support under Grant No. DE-EE0036533 awarded by the Department of Energy. The government has certain rights in the invention.

### BACKGROUND OF PRESENTLY DISCLOSED SUBJECT MATTER

The disclosure deals with system and methodology subject matter for source-agnostic time-domain directional relays for power grid applications, and concerns generally subject matter involving in some embodiments directional relays, inverter based resources, time-domain relays, power system and feeder protection, transmission, and distribution subject matter.

Our presently disclosed subject matter uses a technology that uses the time-domain values of voltages and currents in power systems to determine the direction of current. This makes it immune to all problems of “polarization” faced by legacy relays and enables reliable determination of current-direction in any system topology—transmission and distribution fed by any source, including renewables, which are inverter based resources. The presently disclosed subject matter can fit into any existing numerical relay, as they all sample time-domain values before converting them to phasors. We simply use the time-domain values.

Present technology in extensively deployed numerical directional relays is designed in phasor domain, which requires polarization mechanism to determine direction of current. This is observed to fail in presence of renewables. For example, such approaches are using phasor based solutions which have been shown in field to be failing in presence of inverter based resources.

The presently disclosed subject matter provides reliable determination of current direction in healthy and in faulted power transmission and distribution systems, fed by any type of power sources, including but not limited to synchronous, solar, wind and storage.

Since presently disclosed subject matter can fit into any existing numerical relay, and it is now known that the legacy method is failing, there is an extremely large market for the presently disclosed subject matter.

### Summary of Presently Disclosed Subject Matter

Aspects and advantages of embodiments of the present disclosure will be set forth in part in the following description, or may be learned from the description, or may be learned through practice of the embodiments.

It is a present object to provide improved energy related arrangements, and associated methodology. It is a more particular object, in some instances, to provide improved system and methodology subject matter for source-agnostic time-domain directional relays for power grid applications, including system and methodology subject matter for Inverter based resources (IBRs) which are instrumental in facilitating the integration of renewable energy resources into the power grid. IBRs exhibit unique fault characteristics significantly different from synchronous generators (SGs), dictated by their proprietary controls, posing challenges for the reliable operation of directional relays designed in phasor domain. This disclosure relates to a source-agnostic directional relay formulated in time domain, thus making any polarization unnecessary. It is immune to decaying dc offset and pre-fault currents, and applicable to transmission and distribution feeders with up to 100% IBR penetration. Its performance is superior to a numerical commercial relay in a hardware in the loop setup, and its chosen sampling rate of 24 or more samples per cycle (spc) makes it readily implementable in commercial numerical relays.

The presently disclosed subject matter uses a technology that uses the time-domain values of voltages and currents in power systems to determine the direction of current, which makes the disclosed subject matter able to fit into any existing numerical relay, as they all sample time-domain values before converting them to phasors, and it simply uses the (unconverted) time-domain values.

The result is that the presently disclosed subject matter can provide reliable determination of current direction in healthy and in faulted power transmission and distribution systems. The determination can be made, when fed by any type of power sources, including but not limited to synchronous, solar, wind and storage.

It is to be understood that the presently disclosed subject matter equally relates to associated and/or corresponding methodologies. One exemplary such methodology relates to operating a source-agnostic time-domain-based directional relay for use in a power grid, comprising associating a relay with or without having one or more inverter-based resources (IBRs) providing power to the power grid; acquiring measurement data comprising filtered instantaneous time-domain values of voltage and current measurements vs(t) and is(t) taken from the power grid at a low sampling rate; and determining the direction of current in the relay without converting the time domain samples to phasors at operating frequency of power systems.

Other example aspects of the present disclosure are directed to systems, apparatus, tangible, non-transitory computer-readable media, user interfaces, memory devices, and electronic devices for source-agnostic time-domain directional relay technology. To implement methodology and technology herewith, one or more processors may be provided, programmed to perform the steps and functions as called for by the presently disclosed subject matter, as will be understood by those of ordinary skill in the art.

Another exemplary embodiment of presently disclosed subject matter relates to a source-agnostic time-domain-based directional relay for use in a power grid, comprising a relay having a plurality of respective directional elements, associated with a power grid with or without having one or more inverter-based resource (IBR) providing power to the power grid; measurement sensors acquiring data that are filtered to yield instantaneous time-domain values of voltage and current measurements vs(t) and is(t) taken from the power grid at a low sampling rate; and one or more sensor processors programmed for determining the direction of current in the relay without converting the time-domain values to phasors at operating frequency of power systems.

Additional objects and advantages of the presently disclosed subject matter are set forth in, or will be apparent to, those of ordinary skill in the art from the detailed description herein. Also, it should be further appreciated that modifications and variations to the specifically illustrated, referred and discussed features, elements, and steps hereof may be practiced in various embodiments, uses, and practices of the presently disclosed subject matter without departing from the spirit and scope of the subject matter. Variations may include, but are not limited to, substitution of equivalent means, features, or steps for those illustrated, referenced, or discussed, and the functional, operational, or positional reversal of various parts, features, steps, or the like.

Still further, it is to be understood that different embodiments, as well as different presently preferred embodiments, of the presently disclosed subject matter may include various combinations or configurations of presently disclosed features, steps, or elements, or their equivalents (including combinations of features, parts, or steps or configurations thereof not expressly shown in the figures or stated in the detailed description of such figures). Additional embodiments of the presently disclosed subject matter, not necessarily expressed in the summarized section, may include and incorporate various combinations of aspects of features, components, or steps referenced in any summarized objects herewith, and/or other features, components, or steps as otherwise discussed in this application. Those of ordinary skill in the art will better appreciate the features and aspects of such embodiments, and others, upon review of the remainder of the specification, and will appreciate that the presently disclosed subject matter applies equally to corresponding methodologies as associated with practice of any of the present exemplary devices, and vice versa.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE FIGURES

A full and enabling disclosure of the present subject matter, including the best mode thereof to one of ordinary skill in the art, is set forth more particularly in the remainder of the specification, including reference to the accompanying figures in which:

FIG. 1(a) graphically illustrates a comparison chart of anticipated energy mix over time;

FIG. 1(b) illustrates a comparison chart of anticipated renewable energy mix over time;

FIG. 2 illustrates a single-phase schematic representation of an exemplary three-bus power system;

FIGS. 3(a) and 3(b) respectively illustrate graphical representations of vs, vf and A for forward fault (FIG. 3(a)) and reverse fault (FIG. 3(b)) conditions;

FIG. 3(c) illustrates a graphical representation of components of y for the forward fault in FIGS. 3(a) and 3(b);

FIG. 4 illustrates a schematic representation of an exemplary three-bus unbalanced line model;

FIG. 5 graphically illustrates phasor magnitudes of the 120 Hz component of yₐ during AG faults with different exemplary fault resistances;

FIG. 6 diagrammatically illustrates a plot of dy/dt (Eq. 13) using the waveforms of vs, vf and A as represented in FIGS. 3(a) and 3(b) with magnitude scaled down to unity, for both forward and reverse faults, which show positive and negative values of dy/dt for forward and reverse fault, respectively;

FIG. 7 graphically represents a block diagram of a presently disclosed relay, for operation in accordance with presently disclosed methodology/technology;

FIG. 8(a) schematically illustrates an exemplary 230 kV transmission system fed by an SS (synchronous source) at both ends;

FIG. 8(b) schematically illustrates an exemplary 230 kV transmission system fed by an IBR (Inverter-based resource) at one end and an SS (synchronous source) at the other end;

FIG. 9 graphically illustrates a dynamic reactive current injection reference curve implemented in the control logic of an exemplary IBR such as represented in FIG. 8(b);

FIG. 10 schematically illustrates an exemplary transmission system, forming an experimental test setup with IEEE 13-bus feeder, to test performance of the disclosed system and methodology in highly unbalanced distribution systems featuring multiple IBRs;

FIG. 11(a) graphically illustrates unfiltered and filtered phase a voltage waveforms during an AG fault in the line for vsₐ;

FIG. 11(b) graphically illustrates unfiltered and filtered phase a current waveforms during an AG fault in the line for isₐ;

FIG. 12 graphically illustrates magnitude of the 120 Hz component of distance calculated by the AG element of the relay during an AG fault;

FIG. 13 graphically illustrates derivative of the distance calculations measured by the AG element of the presently disclosed exemplary relay technology;

FIGS. 14(a), 14(b), and 14(c) graphically represent scaled values of dy/dt calculated by the relay 32T₁ when fed by SS for faults at 3 km (FIG. 14(a)), 60 km (FIG. 14(b)), and 147 km (FIG. 14(c)), respectively, on the line;

FIGS. 15(a), 15(b), and 15(c) graphically represent scaled values of dy/dt calculated by the relay 32T₂ when fed by SS for faults at 3 km (FIG. 15(a)), 60 km (FIG. 15(b)), and 147 km (FIG. 15(c)), respectively, on the line;

FIGS. 16(a), 16(b), and 16(c) graphically represent scaled values of dy/dt calculated by the relay 32T₁ when fed by an IBR for faults at 3 km (FIG. 16(a)), 60 km (FIG. 16(b)), and 147 km (FIG. 16(c)), respectively, on the line;

FIGS. 17(a), 17(b), and 17(c) graphically represent scaled values of dy/dt calculated by the relay 32T₂ when fed by an IBR for faults at 3 km (FIG. 17(a)), 60 km (FIG. 17(b)), and 147 km (FIG. 17(c)), respectively, on the line;

FIGS. 18(a), 18(b), 18(c), 18(d), 18(e), and 18(f) graphically represent scaled values of dy/dt calculated by 32T₁ for faults at 100 ft (FIG. 18(a)), 32T₁ for faults at 500 ft (FIG. 18(b)), 32T₁ for faults at 900 ft (FIG. 18(c)), 32T₂ for faults at 100 ft (FIG. 18(d)), 32T₂ for faults at 500 ft (FIG. 18(e)), and 32T₂ for faults at 900 ft (FIG. 18(f)), respectively, on the line in grid connected mode of operation;

FIGS. 19(a), 19(b), 19(c), 19(d), 19(e), and 19(f) graphically represent scaled values of dy/dt calculated by 32T₁ for faults at 100 ft (FIG. 19(a)), 32T₁ for faults at 500 ft (FIG. 19(b)), 32T₁ for faults at 900 ft (FIG. 19(c)), 32T₂ for faults at 100 ft (FIG. 19(d)), 32T₂ for faults at 500 ft (FIG. 19(e)), and 32T₂ for faults at 900 ft (FIG. 19(f)), respectively, on the line in islanded mode of operation;

FIGS. 20(a) and 20(b) graphically illustrate the magnitude of the 120 Hz component of yₐ measured by the relay 32T₁ during capacitor bank switching in an exemplary 230 kV transmission system (FIG. 20(a)), and in an exemplary IEEE 13-bus test feeder (FIG. 20(b), respectively;

FIGS. 21(a) and 21(b) graphically illustrate the magnitude of the 120 Hz component of yₐ measured by the relay 32T₁ when the motor starts at bus 680 (FIG. 21(a)), and bus 671 (FIG. 21(b)), in the exemplary IEEE 13 bus test feeder;

FIG. 22 schematically represents an exemplary presently disclosed test setup with presently disclosed hardware relay and RTDS (Real Time Digital Simulator) technology, a real-time simulator applied for power systems providing power systems simulation technology;

FIGS. 23(a), 23(b), and 23(c) graphically illustrate directions asserted by 32Q₁ directional element when fed by an IBR (FIG. 23(a)), by 32Q₁ directional element when fed by an SS (FIG. 23(b)), and by the presently disclosed relay technology using the samples from 32Q₁ (FIG. 23(c));

FIGS. 24(a), 24(b), and 24(c) graphically illustrate directions asserted by 32Q₂ directional element when fed by an IBR (FIG. 24(a)), by 32Q₂ directional element when fed by an SS (FIG. 24(b)), and by the presently disclosed relay technology using the samples from 32Q₂ FIG. 24(c)); and

FIG. 25 graphically illustrates a TABLE I comprising representative “DIRECTIONAL RELAY ELEMENTS AND THEIR OPERATION.”

Repeat use of reference characters in the present specification and drawings is intended to represent the same or analogous features, elements, or steps of the presently disclosed subject matter.

### DETAILED DESCRIPTION OF PRESENTLY DISCLOSED SUBJECT MATTER

Reference will now be made in detail to various embodiments of the disclosed subject matter, one or more examples of which are set forth herein. Each embodiment is provided by way of explanation of the subject matter, not limitation thereof. In fact, it will be apparent to those skilled in the art that various modifications and variations may be made in the present disclosure without departing from the scope or spirit of the subject matter. For instance, features illustrated or described as part of one embodiment, may be used in another embodiment to yield a still further embodiment.

As used herein, the term “or” is inclusive unless stated otherwise. For instance, if a computer requires A or B to be true in order to perform operation C, the case of both A and B being true will satisfy the condition necessary for C to occur. That is, “or” is inclusive of A, B, and A and B.

The disclosure deals with system and methodology subject matter for source-agnostic time-domain directional relays for power grid applications. Such technology may preferably include such as system and methodology subject matter for Inverter based resources (IBRs) which are instrumental in facilitating the integration of renewable energy resources into the power grid.

### I. INTRODUCTION

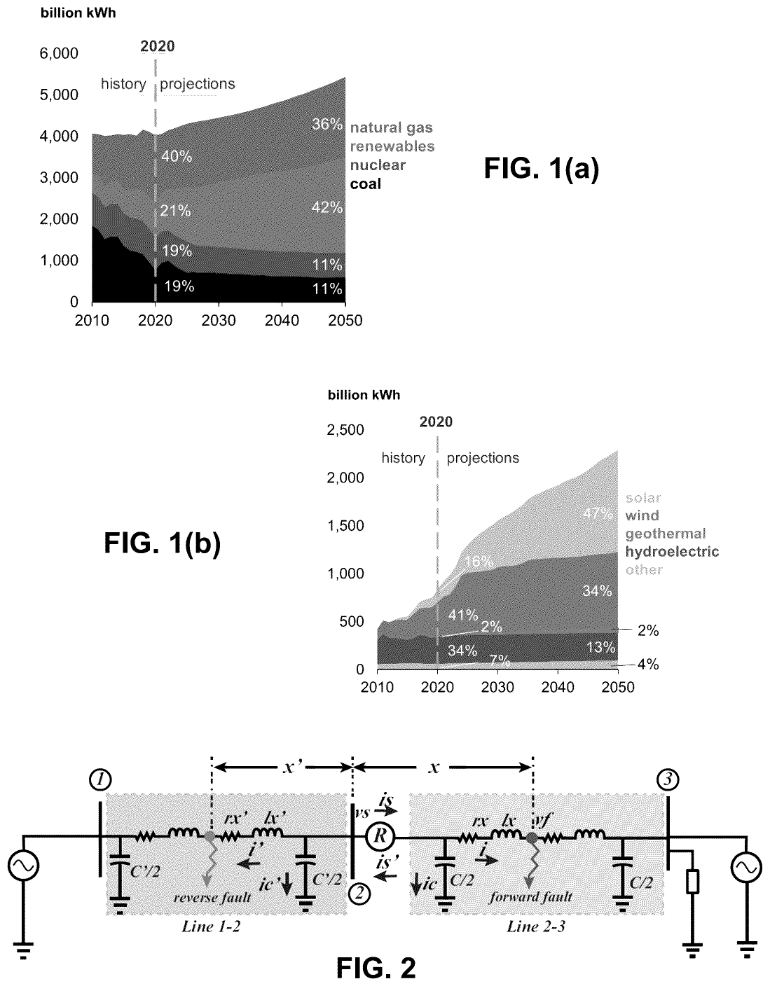

The power grid has witnessed a surge in the integration of renewable energy resources (RERs) driven by growing environmental concerns and the pressing demand for sustainable energy solutions [1]. For example, renewables and IBRs are growing such that 42% energy mix is expected to be from renewable by 2050, with 47% of such renewable from solar and 34% from wind. Wind and solar sources integrate to the grid via IBRs. Achieving such goals require more IBRs integration into the transmission system. FIG. 1(a) illustrates a comparison chart of anticipated energy mix over time, and FIG. 1(b) illustrates a comparison chart of anticipated renewable energy mix over time, according to authoritative indicators [34].

Consequently, there has been a significant increase in the penetration of IBRs as the interface for RERs at both transmission and distribution levels. This paradigm shift impacts the traditional grid protection designed around SGs. The proprietary controls of IBRs exhibit two characteristics that impact the legacy directional overcurrent relays significantly: 1) the fault current is limited to values comparable to load currents (1-1.5 pu of rated current); 2) absence of negative sequence current even while feeding unbalanced load or faults [2], [3]. Even with recent standards such as the IEEE 2800-2022 mandating IBRs to supply negative sequence currents during unbalanced faults, the phase angle modification between output voltage and current from the inverter, driven by diverse manufacturer control schemes, make the fault response from IBRs distinct compared to SGs.

This unusual fault response of IBRs impacts the operation of directional elements designed for systems with SGs. Impacts of IBRs on polarization techniques (self-polarization, cross-polarization) routinely used in directional elements are presented in [4]; the report attributes the problems to weaker voltage support and rapid change in output voltage from the inverter. Although low voltage ride through (LVRT) requirements in recent grid codes aim to address these concerns, output power factor control dictated by the grid codes impacts the operation of directional elements. Negative sequence directional (32Q) and directional overcurrent (67Q) elements suffer from sensitivity decline and failure in operation due to the curtailment of negative sequence current (I₂) and changed angular relationship between negative sequence voltage (V₂) and I₂ caused by inverters as reported in multiple studies [5]-[8]. Field observations reported in [9] further validate the misoperation of the 32Q element in the presence of IBRs. Misoperation of Negative sequence component based directional element occurs due to such factors. Phase component based directional relays used in electromechanical relays require voltage-polarization: loss of polarizing voltage causes the misoperation of such relays.

Directional elements are essential for the security and selectivity of a protection scheme performing crucial tasks of supervising distance elements and controlling overcurrent elements [10]; their misoperation poses a significant risk to system protection and reliability.

Several approaches have been proposed to address these challenges. Some solutions involve modifying the inverter's control scheme to maintain the desired voltage-current relationship for proper relay operation [11]-[13]. However, these control-based solutions face practical limitations as inverter controls are proprietary and inaccessible to utilities. Chowdhury et al. [14]propose modifying the existing relay settings, such as raising the supervisory overcurrent threshold and utilizing positive sequence current supervision to compensate for the impacts of IBRs on the 32Q element. Nonetheless, such settings are IBR dependent—they rely on specific IBRs supplying I₂ and lose dependability when the system is fully converter-interfaced with IBRs providing minimal or no I₂. In contrast, the authors in [15] demonstrate that the traditional phase component-based directional methods outperform negative sequence component-based directional elements in the presence of IBRs. However, phasor-based directional elements, reliant on polarizing quantities, are susceptible to failure in presence of IBRs due to rapid changes in output voltage [16] that impact existing polarization techniques.

Other proposed solutions, such as the high-speed protection system with a directional feature based on traveling waves by Namdari et al. [17], face limitations when faults occur at the instant of zero crossing of the phase voltage, as no traveling waves are launched in such scenarios. A time-domain distance relay with an inherent directional feature is proposed in [18], but the relay uses a sample from the other end in presence of fault resistance. Similarly, in [19], a time-domain directional relay that operates solely on fault current is proposed. But, the paper uses an empirically derived function for fault detection that lacks a foundation in physics, raising concerns about its applicability to other systems, such as transmission systems, or islanded distribution systems with multiple IBRs that are not studied. It does not provide fault classification and overlooks security aspects during disturbances, despite claiming a low tripping time of 3.32 ms. Additionally, model and controls of the inverters used for the solar farm, that critically define its response to disturbances, are not described. These limitations raise concerns about the method's reliability and broader applicability.

Therefore, there is a need for a comprehensive, source-agnostic and system-independent directional relay. The presently disclosed relay addresses these requirements and is further immune to decaying dc offsets, prefault currents and fault resistance.

It can operate at a sampling rate as low as 24 spc, making it suitable for implementation in existing numerical relays while eliminating the need for any polarization techniques.

This disclosure is structured as follows: Section II provides the derivation of the method with the complete formulation. Test systems utilized for the validation of the presently disclosed scheme are discussed in Section III. Section IV presents the discussion and analysis of the results of the presently disclosed relay under various test scenarios. Finally, Section V concludes this disclosure highlighting the key contributions of the disclosure.

### II. METHODOLOGY

### A. Formulation of the Method

A single-phase schematic representation of an exemplary three-bus power system is shown in FIG. 2, where the relay R with CT connections set for forward direction to protect line 2-3 is placed at bus 2. The voltage and current measurements vs(t) and is(t) are available at the sending end (bus 2). Let r and I be the resistance and inductance of the line per unit length, respectively, and C the total capacitance of the line 2-3. The line can then be represented by a ‘hybrid Pi’ circuit, where the shunt capacitor is lumped, but series parameters are distributed. The instantaneous current through the capacitor, ic(t), is given by

$$ic ( t ) = \frac{C}{2} \frac{d v s ( t )}{dt} , \qquad ( 1 )$$

and the line current, i(t), is

$$i ( t ) = is ( t ) - ic ( t ) = is ( t ) - \frac{C}{2} \frac{d v s ( t )}{dt} \qquad ( 2 )$$

For a three phase fault on the transmission line 2-3 at a distance x from the relay, Kirchoff's voltage law (KVL) from the sending end up to the fault point yields:

$$v s = v f + ( ri + l \frac{di}{dt} ) x = v f + Ax \qquad ( 3 )$$

where, vf is the voltage at the fault point and A represents the voltage drop in the line section per unit length. Since all measured quantities are instantaneous (time-domain), for convenience, the notation (t) is dropped from already defined quantities hereafter.

In (3), the line parameters are known, vs is measured, and is calculated using (2). The time derivatives of measured quantities vs and i used in (3) and (2) are calculated numerically using finite difference approximation: if i(t−Δt) and i(t) are the sampled values of i at successive samples, the time derivative of i at time tis given by,

$$\frac{di}{dt} ( t ) = \frac{i ( t ) - i ( t - Δ t )}{Δ t} , \qquad ( 4 )$$

where Δt is the sampling time step. Once the derivatives are calculated, the only unknown quantities in (3) are vf and x. Although the lower sampling rate used by the relay introduces some errors in the derivative calculation, this does not affect the accuracy of the direction calculation—as it will be shown later, the method uses the sign of the derivatives calculation instead of the actual values.

Let us now consider a case with reverse fault, with fault on line 1-2 at a distance x′ behind the relay. For the relay with CT polarity set for forward direction, the current measured by the relay for reverse fault will have opposite polarity with respect to the current measured during a forward fault. Also, the current ic and ic′ are negligible compared to the line currents land i′ in FIG. 2, which yields:

$${i}^{′} = - i \qquad ( 5 )$$

With vs being the voltage measured by the relay, KVL between bus 2 and the fault point gives

$$v s = v f + ( {ri}^{′} + l \frac{{di}^{′}}{dt} ) {x}^{′} \qquad ( 6 )$$

Using (5) in (6) we get,

$$v s = v f + ( ri + l \frac{di}{dt} ) ( - {x}^{′} ) \qquad ( 7 )$$

Comparing equation (7) with (3), we observe that the distance calculated by the relay for reverse fault is −x′, which is clearly a negative number. This shows that the formulation of the method is inherently directional, i.e., the value of x calculated is positive for forward faults and negative for reverse faults. Also, note that the formulation inherently includes decaying dc offsets and pre-fault currents. However, since the fault voltage vf is unknown and depends on the fault resistance, it is necessary to formulate (i.e., represent) such equation as a method that is able to identify the direction of the fault irrespective of the fault resistance.

Dividing both sides of (3) by A, we get

$$y ( t ) = \frac{vs ( t )}{A ( t )} = \frac{vf ( t )}{A ( t )} + x \qquad ( 8 )$$

Since vs, vf and A in (3) are sinusoidal quantities, taking vs as reference, let these quantities be represented by

$$\begin{matrix}vs ( t ) = {Vs}_{m} sin ( ω t ) & ( 9 ) \\ vf ( t ) = {Vf}_{m} sin ( ω t + {ϕ}_{f} ) & ( 10 ) \\ A ( t ) = {A}_{m} sin ( ω t + {ϕ}_{a} ) & ( 11 )\end{matrix}$$

Using (9) and (11) in (8), we get:

$$y ( t ) = \frac{{Vs}_{m} sin ( ω t )}{{A}_{m} sin ( ω t + {ϕ}_{a} )} . \qquad ( 12 )$$

Differentiating (12) with respect to t, using the quotient rule, we get

$$\frac{dy ( t )}{dt} = \frac{ω {Vs}_{m}}{{A}_{m}} \cdot c {osec}^{2} ( ω t + {ϕ}_{a} ) \cdot sin ( {ϕ}_{a} ) \qquad ( 13 )$$

In (13), all the terms are positive except sin(ϕₐ), which determines the sign of dy/dt based on the value of ϕₐ, i.e.,

$$\frac{dy}{dt} = \{ \begin{matrix}positive , & for {ϕ}_{a} ∈ [ 0 , π ] \\ negative , & for {ϕ}_{a} ∈ [ - π , 0 ]\end{matrix} \qquad ( 14 )$$

In an R-L circuit representing a transmission line, the impedance always has a positive angle. Consequently, during a fault in the line, the fault voltage vf will always lag behind the measured voltage vs at the relay terminal. Based on this observation, it is shown in the following discussion that forward faults exclusively result in conditions where ϕₐ∈[0, π], while reverse faults exclusively yield ϕₐ∈[−π, 0]. Leveraging this insight in (14), we disclose employing dy/dt as the direction discrimination function.

For forward faults, the quantity A from (3) can be written as:

$$A = \frac{vs - vf}{\vert x \vert} \qquad ( 15 )$$

where |x| replaces x as the distance calculated for forward faults are positive. In (15), vf is unknown; the only information we have on vf is that it lags vs.

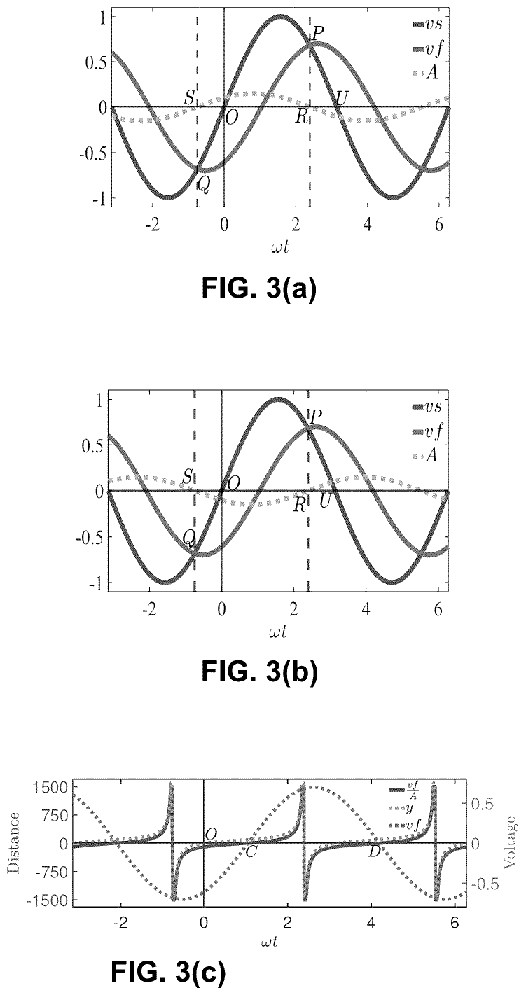

FIGS. 3(a) and 3(b) respectively illustrate graphical representations of vs, vf and A for forward fault (FIG. 3(a)) and reverse fault (FIG. 3(b)) conditions, while FIG. 3(c) illustrates a graphical representation of components of y for the forward fault in FIGS. 3(a) and 3(b). The waveform representing vs in (9) with unit amplitude is shown in FIG. 3(a), along with a signal that lags vs, let this signal be a representation of vf During a complete cycle of the sine wave, vs and vf become equal at two instances (points P and Q). Notably, from (15), when vs=vf, A=0 (points Rand S). Also, since vf lags vs, vs >vf between points P and Q, from (15), A must also be positive in that interval. Knowing the two zero crossing points and the sign of A between the two points, we can draw A as shown in FIGS. 3(a) and 3(b). As the angle between vf and vs changes between 0 and π (any possible case), irrespective of the amplitude of vf point P moves along vs between O and U, and the zero crossing of A (point R) moves horizontally between O and U, so that A always leads vs by an angle between O and π. Thus, the graphical illustration demonstrates that for a forward fault, A always leads vs, implying that ϕa∈[0, π]. Recalling (14), we can confirm that the sign of dy/dt is always positive for forward faults.

Similar reasoning can be extended to reverse faults, where the distance calculated according to (3) is negative. Replacing x with −|x| in (3), equation (15) for reverse fault becomes:

$$A = \frac{vs - vf}{- \vert x \vert} = \frac{vf - vs}{\vert x \vert} \qquad ( 16 )$$

The time domain waveforms of vs and vf for a reverse fault at the same distance as that for the forward fault are depicted in FIG. 3(b). Between the zero crossings of A (points Sand R), where vs>vf A is negative according to (16). As vf lags vs by an angle between 0 and τ (any possible case), the point R moves along the ωt ax is between O and U. Clearly, A always lags behind vs for a reverse fault, unlike for forward faults. This shows that for reverse faults, ϕₐ∈[−π, 0], which implies from (14) that dy/dt is always negative for reverse faults. Notice that the observations here are based on the physics of the fault and are not simply anecdotal. Therefore, the conditions for forward and reverse faults are always mutually exclusive, justifying using the sign of dy/dt as the direction discrimination function.

FIG. 3(c) shows the behavior of y, as described in (8), as we shall be using this behavior in Section II-C. Clearly, vf/A becomes zero when vf is zero (points C and D in FIG. 3(c)), completing one full cycle while vf completes half a cycle. In this interval, when A is zero, the quantity vf/A is theoretically infinite, but since we calculate A after every new sample, we know when A is zero, and we limit the value of vf/A at that instant to a finite value (±1500 in FIG. 3(c)). Thus, clearly, the signal vf/A is periodic with twice the fundamental frequency (120 Hz). This follows the mathematical pattern of the tan or cot functions, which exhibit similar behavior. This second harmonic will also appear in the trace of y, which will additionally have a dc shift equal to the fault distance x, as per (8), as seen in FIG. 3(c). This fact will be used to detect faults in Section II-C.

### B. Extension of the Method for Unbalanced Faults on Three-Phase Balanced and Unbalanced Lines

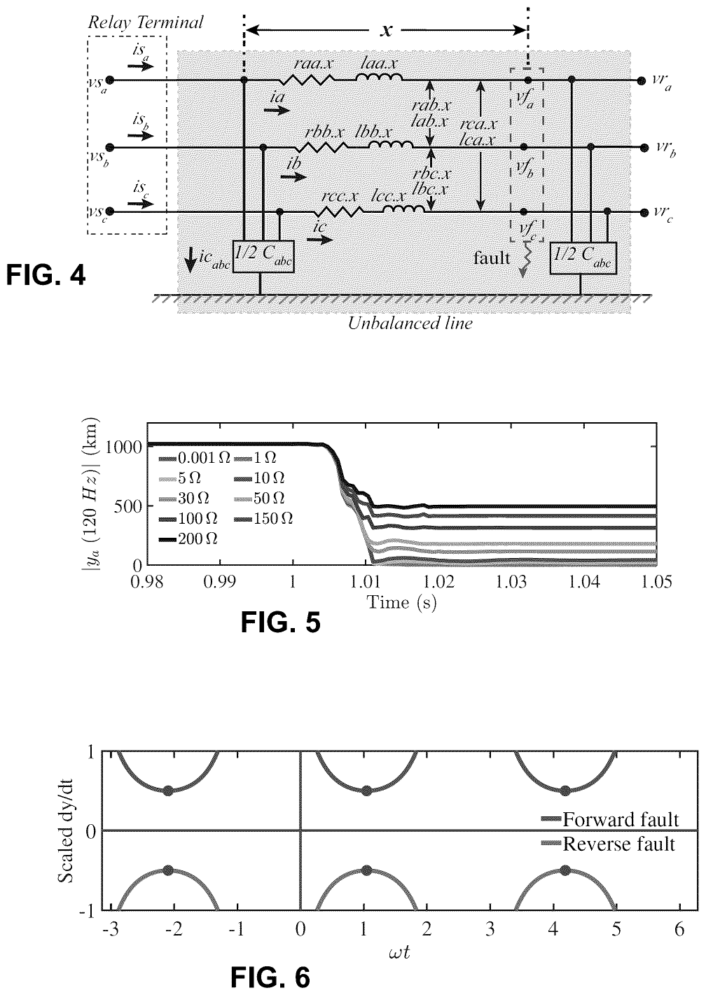

The concept of directional element can be extended to unbalanced faults on three phase balanced and unbalanced lines by writing KVL between the sending end and the fault point, considering the mutual coupling between the phases. FIG. 4 illustrates a schematic representation of an exemplary three-bus unbalanced line model. KVL for phase a can be expressed as:

$${vs}_{a} = {vf}_{a} + [ {r}_{aa} ia + {l}_{aa} \frac{dia}{dt} + {r}_{ab} ib + {l}_{ab} \frac{dib}{dt} + {r}_{a c} ic + {l}_{a c} \frac{dic}{dt} ] x \qquad ( 17 )$$

where, x is the distance to fault and vf denotes the fault voltage for phase-a. The line parameters include self and mutual resistances and inductances per unit length. The line currents ia, ib, and ic in (17) are obtained by subtracting the current through the capacitor (icₐ, ic_{b}, and ic_{c}) from the currents measured by the relay (isₐ, is_{b}, and is_{c}), respectively. Equation (17) can be simplified as:

$${vs}_{a} = {vf}_{a} + {A}_{a} x \qquad ( 18 )$$

where the voltage drop per unit length of phase a

$${A}_{a} = [ {r}_{aa} ia + {l}_{aa} \frac{dia}{dt} + {r}_{ab} ib + {l}_{ab} \frac{dib}{dt} + {r}_{a c} ic + {l}_{a c} \frac{dic}{dt} ] . \qquad ( 19 )$$

Similarly, we can express (18) for other two phases as:

$$\begin{matrix}{vs}_{b} = {vf}_{b} + {A}_{b} x & ( 20 ) \\ {vs}_{c} = {vf}_{c} + {A}_{c} x & ( 21 )\end{matrix}$$

Notice the similarity between equations (18) and (3); for a fault involving phase a and ground, the deduction of the directional element y from (3) can be extended to the KVL equation for phase a to obtain the directional element yₐ which is defined by:

$${y}_{a} = \frac{{vs}_{a}}{{A}_{a}} . \qquad ( 22 )$$

When a fault involves phase-a and ground, the fault voltage vfₐ lags behind vsₐ. Utilizing the arguments made for the direction identification using a single phase element y, we can use dyₐ/dt as the direction discrimination function.

For faults involving two phases, such as a line-to-line fault between phase b and c, we can use (20) and (21) to derive directional element y_{bc}.

$${y}_{bc} = \frac{{vs}_{b} - {vs}_{c}}{{A}_{b} - {A}_{c}} = \frac{{vs}_{bc}}{{A}_{bc}} \qquad ( 23 )$$

Similarly, we can formulate other two ground and phase directional elements, resulting in a total of six directional elements that cover all types of faults. FIG. 25 (Table I) summarizes the different relay units, the corresponding directional elements, and the faults for which the relay units can be employed to identify the fault direction.

### C. Relay Functionalities

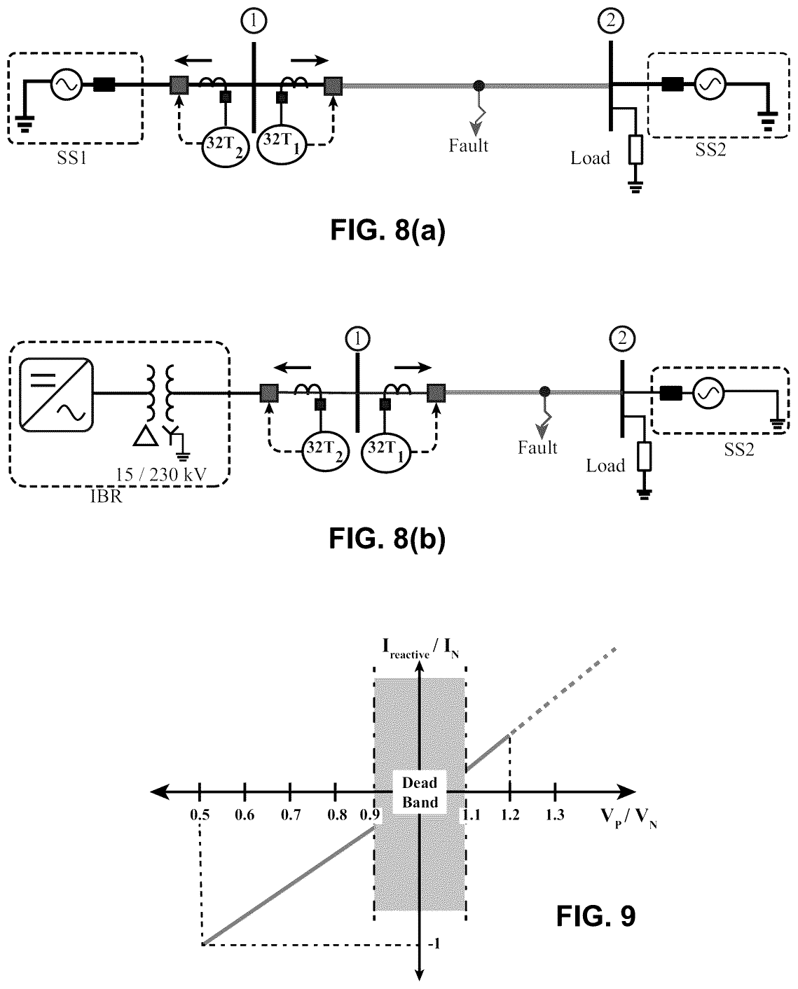

1) Fault Detection: As illustrated in Section II-A, vf/A is a periodic signal at 120 Hz frequency. The fault detection process involves calculation of the phasor magnitude of the 120 Hz component of the distance calculations using Discrete Fourier Transform (DFT) for each directional element. The phasor magnitudes of the 120 Hz components of yₐ for AG faults (with varying fault resistances (Rf)) at 75 km from bus 1 on the line in the test system of FIG. 8(a) (fault starts at 1 sec into the simulation) are depicted in FIG. 5. Observe that the larger Rf values result in larger vfa, resulting in larger phasor magnitude of the 120 Hz component (it is zero for bolted fault). Also, observe that the component is much higher when there is no fault, as vf will equal the healthy (pre-fault) voltage at the fault point.

In FIG. 5, even for a very high fault resistance of 200Ω, the magnitude of the 120 Hz component of yₐ during fault is significantly lower (almost 50%) than its pre-fault value. This nature is seen for the distance measured by all directional elements, regardless of fault type or location along the line. Therefore, fault detection is achieved by setting a threshold on the magnitude of the 120 Hz component. Note that such example of 120 Hz may more generally better be referred to as the second harmonic, because outside the USA, the system operating frequency in some instances can be for example 50 Hz (instead of 60 Hz), in which case we will use the 100 Hz component. If any relay element exhibits a magnitude below the threshold, a fault is detected. Based on the simulations described otherwise in this disclosure, the threshold is selected as 80% of the pre-fault value.

2) Selection of Correct Relay Element: The formulation of the method discussed in Section II requires that we select the correct directional element associated with fault. FIG. 25 (Table 1) overviews the relay units operating for different fault types. Ground relay units operate for line-to-ground (LG), doubleline-to-ground (LLG), and three-phase (3 ph) faults, while line relay units work for line-to-line (LL) and 3 ph faults.

Ground faults are characterized by the presence of zero sequence components. Since transformer connections (e.g., delta on the line side) can cause the zero-sequence current measured by the relay to be zero even during a ground fault, zero-sequence voltage is chosen as the measure for the distinction between ground and phase faults. The relay calculates the zero sequence voltage as the sum of the time domain voltages in all three phases:

$$3 {v}_{0} = {vs}_{a} + {vs}_{b} + {vs}_{c} . \qquad ( 24 )$$

A threshold on the magnitude of 3_{V}_{₀} is set so that if the phasor |3 V₀| obtained using the peak of the 3_{V}_{₀} waveform is greater than the threshold during fault, the relay identifies the fault as a ground fault, otherwise, the fault is labeled as a nonground fault. It is important to determine an appropriate threshold, which depends on a system's unbalance. For balanced (transposed) transmission lines, we expect minimal values of |3_{V}_{₀}| during steady state, but this value may be higher in unbalanced distribution lines. Therefore, the threshold on |3_{V}_{₀}| is chosen based on power flow studies. More than 200% of the value observed in power flow studies is chosen for this disclosure. This amounts to 0.3 kV for the transposed transmission system and 0.23 kV for the unbalanced distribution system analyzed in this disclosure.

Once a fault is identified as a ground or non-ground fault, the relay needs to select the appropriate element to be used for direction. For this, the magnitudes of the three phase voltages measured by the relay are used. Since the voltage at any faulted phase during a fault is lower than that in the healthy phase(s), the relay chooses the directional element corresponding to the phases that have the least voltages.

While the voltage-based selection is effective for most practical systems, we should also consider some scenarios where fault is fed by a very strong source that would not produce the voltage dip required to identify the faulted phases. In such scenarios, we disclose an alternative current-based directional element selection procedure tailored to strong systems, which cannot constitute an IBR and have a distinct fault signature (high currents with little voltage variations) that facilitates the choice between voltage and current based selection.

To distinguish ground and non-ground faults, we set a threshold on |3I₀|, chosen at more than 200% of the current unbalance in the system. If |3I₀| (calculated using peaks of 3i₀) exceeds this threshold, the fault is classified as a ground fault and vice versa. For our transposed transmission system with little unbalance, this threshold is taken as 75 A, considering the least value of |3I₀| that results from faults in the system. Following the ground/non-ground fault classification, the directional element is determined based on the phase(s) with currents greater than 200% of the prefault currents. This current-based approach complements the voltage-based strategy and enables phase selection in systems with the weakest to the strongest sources.

3) Direction Identification: Once a correct directional element is selected, the relay uses the corresponding direction discrimination function—the sign of dy/dt is used for this, as described in Section II-A. A plot of dy/dt (13) using the waveforms of vs, vf and A in FIGS. 3(a) and 3(b) with magnitude scaled down to unity, for both forward and reverse faults is shown in FIG. 6, which shows positive and negative values of dy/dt for forward and reverse fault, respectively. The dots in FIG. 6 are the points where dy/dt reaches its minimum (during the forward fault) and maximum (during the reverse fault) values. It can be analytically shown from (13) that the maximum/minimum value of dy/dt will occur at the points,

$$ω t = \pm \frac{π}{2} - {ϕ}_{a} \qquad ( 25 )$$

From (11), it is clear that these points correspond to the peaks of quantity A. Therefore, to determine the fault direction, the relay calculates the derivative dy/dt at the peak of quantity A for each directional element. The sign of the calculated dy/dt determines the direction of the fault.

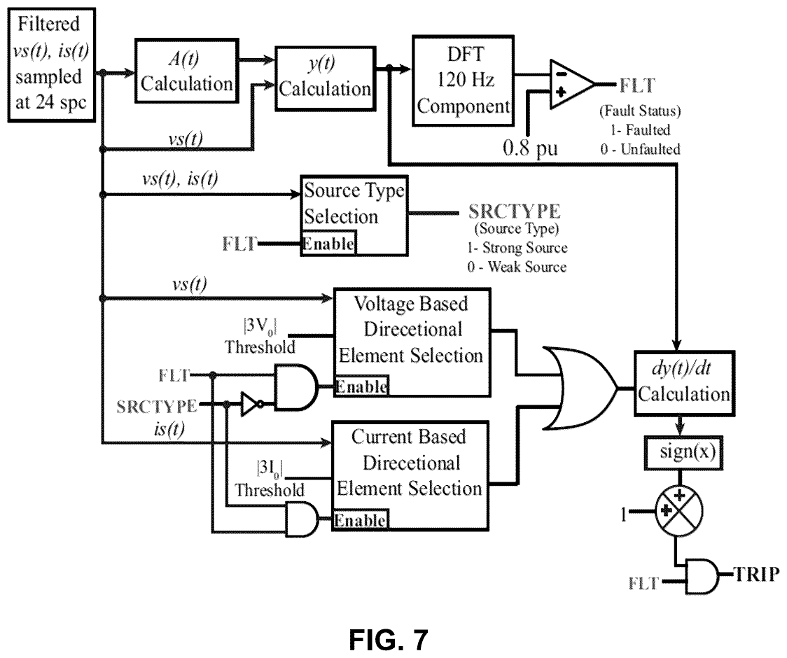

FIG. 7 graphically represents a block diagram of a presently disclosed relay, for operation in accordance with presently disclosed methodology/technology. Source type selection logic and directional element selection logic (both voltage-based and current-based) are enabled only when the fault status is triggered, using the magnitude of the 120 Hz component, as detailed earlier. The source type selection logic, using the voltage and current measurements, distinguishes between strong and weak sources using a fault signature. If a fault is detected and the bus voltages stay above a set threshold (0.95 pu is used in this disclosure) during fault (a characteristic of strong source), the logic designates a strong source (SRCTYPE set to 1), and current-based approach is selected, otherwise, the voltage-based approach is selected. Once a directional element is chosen, the relay evaluates dy/dt corresponding to that element. If the value of dy/dt is positive and the fault still persists, a trip signal is generated.

### III. SYSTEM DESCRIPTION

The presently disclosed method is tested in three different test systems described in this Section.

### A. Transmission System Fed by Synchronous Sources

FIG. 8(a) schematically illustrates an exemplary 230 kV transmission system fed by an SS (synchronous source) at both ends, while FIG. 8(b) schematically illustrates an exemplary 230 kV transmission system fed by an IBR (Inverter-based resource) at one end and an SS (synchronous source) at the other end. More particularly, the simulation setup shown in FIG. 8(a) featuring a 230 kV transmission line spanning 150 km is modeled using a distributed line model (even line charging capacitance is distributed) in PSCAD/EMTDC. The line is supported by towers arranged in a 3-conductor flat configuration with a spacing of 6 m and a height of 20 m. The lines are modeled as transposed lines as recommended by [20] that suggests the transposition of high voltage transmission lines longer than 100 km.

The system includes two synchronous sources, SS1 and SS2, modeled as Thevenin equivalents with voltage angles (δ) of 15° and 0°, respectively. The positive sequence and zero sequence impedances for SS1 are 79.35 ∠80° Ω and 23.81∠80° Ω, respectively, while these values for SS2 are 74.86φ82° Ω and 22.46∠82° Ω, respectively. A constant-power load with a rating of 150 MVA at 0.9 pf lagging is connected at bus 2. The pre-fault current at rated voltage from bus 1 to bus 2 is 220 A (equivalent to 98/4° MVA).

In this disclosure, we denote the presently disclosed relay as 32T (time-domain directional relay). Two directional relays, 32T₁ and 32T₂ are located at bus 1. Relay 32T₁ is overseeing the line 1-2, while relay 32T₂ is overseeing the system comprising SS1 behind bus 1. Any fault on line 1-2 is in the forward direction for relay 32T₁, whereas, for relay 32T₂, the fault on line 1-2 is in the reverse direction.

### B. Transmission System Fed by IBR and Synchronous Source

This test system is identical to the test system in FIG. 8(a), except that the synchronous source SS1 is replaced by an IBR, as shown in FIG. 8(b). The IBR is a grid-following inverter (GFOL) rated at 100 MVA, 15 kV, controlled to operate at rated load at unity power factor in steady state. The control system for the inverter is derived from [21] with modifications to implement the low voltage ride through characteristics found in the design provided by Siemens [22] for GFOL inverters. The control logic, including governing equations, is explained in detail in [18]. The control system implements dynamic reactive current injection with reactive current priority, blocks negative sequence currents, and limits the current to 1.2 pu of the inverter rating. FIG. 9 graphically illustrates a dynamic reactive current injection reference curve implemented in the control logic of an exemplary IBR such as represented in FIG. 8(b). In particular, reactive current injection may be performed based on the reference curve shown in FIG. 9 [23].

### C. Distribution System

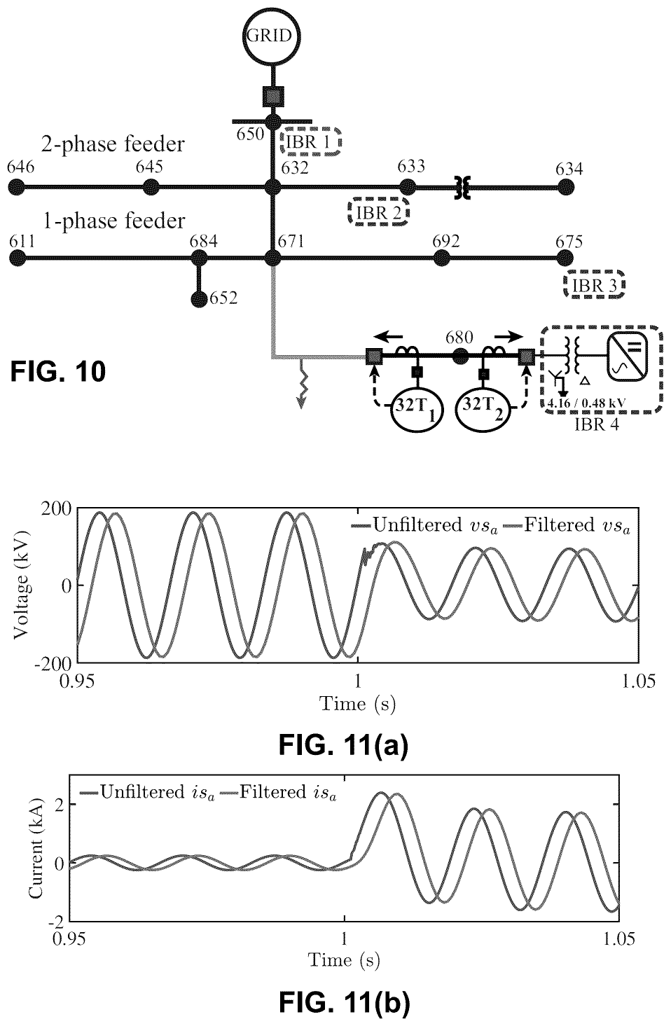

FIG. 10 schematically illustrates an exemplary transmission system, forming an experimental test setup with IEEE 13-bus feeder, to test performance of the disclosed system and methodology in highly unbalanced distribution systems featuring multiple IBRs. In other words, to test the performance of the presently disclosed scheme in highly unbalanced distribution systems featuring multiple IBRs, an experimental test setup with IEEE 13-bus feeder [24], as shown in FIG. 10, may be used. Four inverters are connected to buses 650, 633, 675 and 680, rated at 1500, 1000, 800, and 800 kVA, respectively. Among them, bus 650 accommodates a grid-forming (GFOR) inverter, while the remaining inverters operate as GFOL inverters. The inverter models and control techniques are adopted from [25].

The line between bus 671 and bus 680, a 1000 feet long three phase line with B-A-C-N phasing, is chosen for testing the presently disclosed relay with two relays, 32T₁ and 32T₂, located at bus 680, as shown in FIG. 10. Any fault in the line is in the forward direction for 32T1 and in the reverse direction for 32T2. The presently disclosed method is tested with all types of faults in the line with the system operating in both grid-connected and islanded modes of operation. Notably, the islanded mode presents a rigorous condition, as the system is fed 100% by IBRs.

### IV. RESULTS

The relay algorithm uses time domain samples of voltages (vsₐ, vs_{b}, vs_{c}) and currents (isₐ, is_{b} and is_{c}) as inputs. The waveforms are filtered using a third-order low-pass Butterworth filter with a cutoff frequency of 120 Hz to extract their fundamental components, just as done in conventional relays. The resulting filtered waveforms are then sampled at a low rate of 24 samples per cycle (the method also functions for higher sampling rates). The sampled waveforms are fed to the relay algorithm, which performs the required calculations and determines the fault direction if a fault is detected. The method is extensively tested in all three test systems described in Section III for all four types of faults at different locations on the line with a large range of fault resistances practical to the presently disclosed system under discussion.

A. Application of the Presently Disclosed Method in Transmission System with Synchronous Sources

As a representative case, an AG fault with a fault resistance of 10Ω is simulated at 75 km from the relay at bus 1 in FIG. 8(a), representing a forward fault for relay 32T₁. The unfiltered instantaneous voltage and current input to the relay 32T₁ at phase a, along with their filtered values sampled at 24 samples per cycle, are shown in FIGS. 11(a) and 11(b), respectively. In other words, FIG. 11(a) graphically illustrates unfiltered and filtered phase a voltage waveforms during an AG fault in the line for vsₐ, while FIG. 11(b) graphically illustrates unfiltered and filtered phase a current waveforms during an AG fault in the line for isₐ.

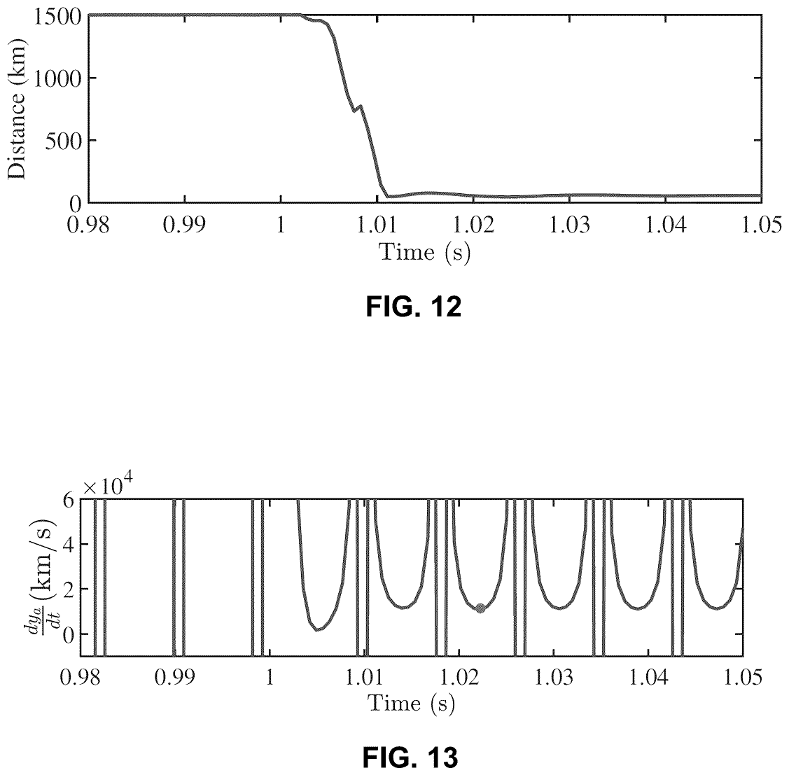

Fault starts at time t=1 s into the simulation. Notice that the filtered fault current (input to the relay) has noticeable dc offset, which affects conventional phasor-based relays. The magnitude of the 120 Hz component of the distance calculated by the AG element of the relay during an AG fault is graphically illustrated in FIG. 12, where the magnitude significantly reduces from 1500 km pre-fault to almost 50 km (3% of the pre-fault value) during fault, providing clear detection of fault.

After fault detection, the relay algorithm checks for zero sequence voltage. For this AG fault, the measured |3_{V}_{₀}| value is 40 kV, exceeding the 0.3 kV threshold and providing the correct categorization as a ground fault. Using phase voltage magnitudes (0.49 pu, 0.92 pu, and 0.95 pu for phases a, b, and c, respectively), the relay selects the AG directional element due to phase a having the least voltage magnitude. At the upcoming peak of Aₐ, the relay evaluates the derivative of distance calculation: dyₐ/dt. FIG. 13 graphically illustrates derivative of the distance calculations measured by the AG element of the presently disclosed exemplary relay technology. In particular, in FIG. 13, we observe a positive derivative (dot), indicating a forward fault. It can be seen that the relay takes less than 1.5 cycles (fault initiates at t=1 s) to determine the fault direction. It is important to note that the relay does not calculate the derivative continuously—once the relay element is identified the relay calculates the derivative only once at the peak of the quantity A corresponding to the selected directional element.

The same procedure when followed for the relay 32T₂, yields a negative value for dyₐ/dt, correctly identifying the fault as reverse AG fault.

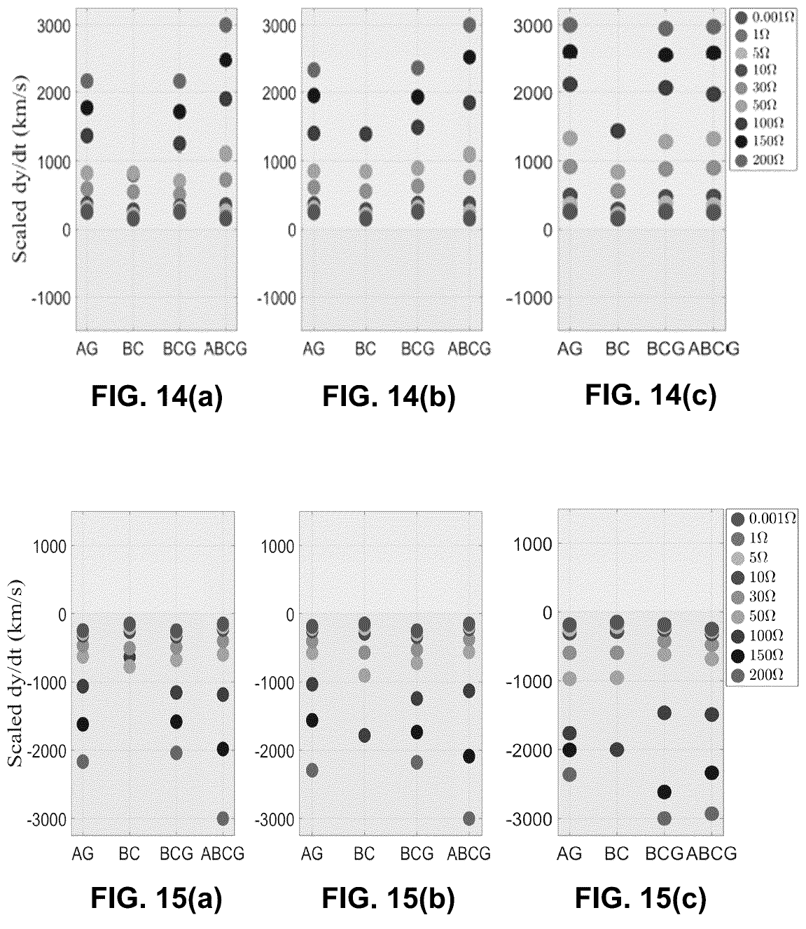

All four types of faults are simulated at 3 km, 60 km and 147 km from the relay with fault resistances up to 200Ω for ground faults and up to 100Ω for line-to-line faults. The selection of fault resistance is based on field observations for high resistance faults in 230 kV systems [26]. Results for both relays 32T₁ and 32T₂ are illustrated in FIG. 14 and FIG. 15 respectively, showing dy/dt measured by each relay. Magnitudes of dy/dt are scaled down to enhance visualization. Note that only magnitudes of dy/dt are scaled, and this scaling is only for presentation purposes which do not impact the result (sign of dy/dt) in any way. In particular, FIGS. 14(a), 14(b), and 14(c) graphically represent scaled values of dy/dt calculated by the relay 32T₁ when fed by SS for faults at 3 km (FIG. 14(a)), 60 km (FIG. 14(b)), and 147 km (FIG. 14(c)), respectively, on the line, while FIGS. 15(a), 15(b), and 15(c) graphically represent scaled values of dy/dt calculated by the relay 32T₂ when fed by SS for faults at 3 km (FIG. 15(a)), 60 km (FIG. 15(b)), and 147 km (FIG. 15(c)), respectively, on the line.

The relay 32T₁ accurately identifies all faults as forward faults with dy/dt values being positive for all the cases, whereas the relay 32T₂ identifies all faults as reverse faults as dy/dt values are negative for all the faults. Notice that dy/dt increases with higher fault resistances, as the fault current will reduce for higher fault resistances, making Aₐ, the voltage drop per unit length smaller, resulting in higher dy/dt based on (13). The presently disclosed method demonstrates exceptional accuracy enabled by the time-domain formulation of the method with an accurate representation of the physics of the fault, which not only exempts the relay from the need for any polarization but also makes the relay immune to pre-fault currents and decaying dc offset in the fault current. The relay's robustness to pre-fault current is further validated by doubling the load on the line in the system depicted in FIG. 8(a). Both relays, 32T₁ and 32T₂, maintained consistent accuracy regardless of the magnitude of the pre-fault current.

B. Application of the Presently Disclosed Method in Transmission System with IBR

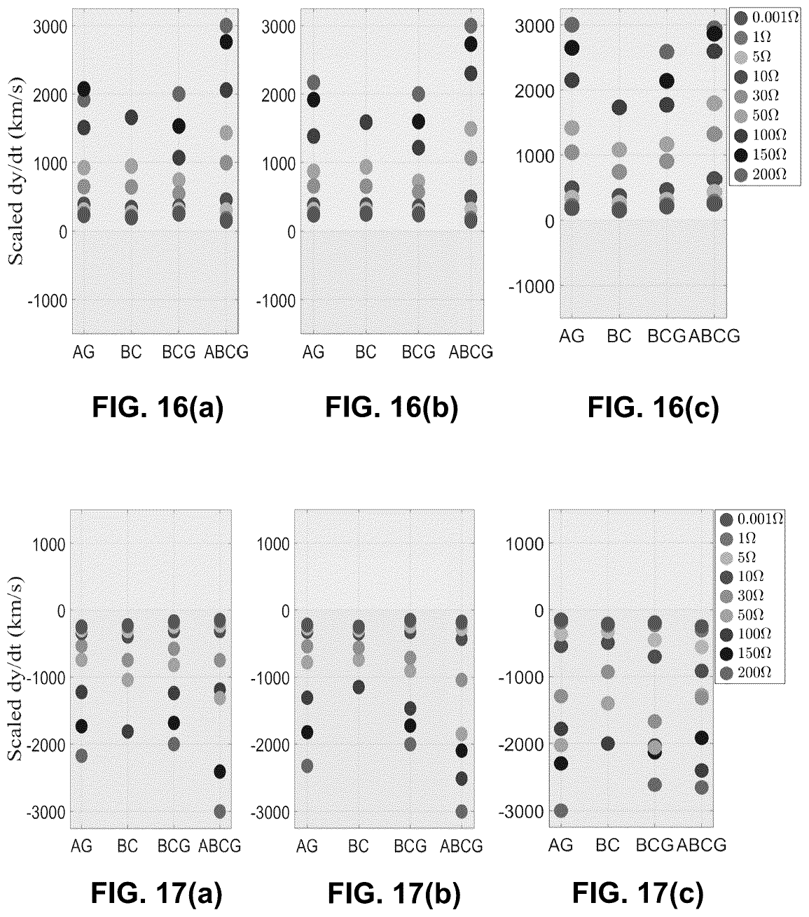

The presently disclosed method is evaluated in the presence of IBRs using the test system in FIG. 8(b). The fault response of the inverter has been presented in [18], showing that the inverter model strictly follows the control scheme described in Section III-B, wherein the fault current is limited to 1.2 pu, and the inverter output current is always purely positive sequence. The results for direction measured by the relay 32T₁ and 32T₂ are presented in FIG. 16 and FIG. 17, respectively, demonstrating the accurate identification of the direction for all faults by both relays. The relays operate consistently and reliably without requiring modifications to their method, regardless of the source feeding the relays. This source-agnostic behavior makes the presently disclosed relay immune to different control schemes implemented in the IBRs. In particular, FIGS. 16(a), 16(b), and 16(c) graphically represent scaled values of dy/dt calculated by the relay 32T₁ when fed by an IBR for faults at 3 km (FIG. 16(a)), 60 km (FIG. 16(b)), and 147 km (FIG. 16(c)), respectively, on the line, while FIGS. 17(a), 17(b), and 17(c) graphically represent scaled values of dy/dt calculated by the relay 32T₂ when fed by an IBR for faults at 3 km (FIG. 17(a)), 60 km (FIG. 17(b)), and 147 km (FIG. 17(c)), respectively, on the line.

The presently disclosed method is further validated with tests conducted by replacing the IBR model in FIG. 8(b) with an IEEE 2800-2022 standard-compliant IBR model sourced from [27]. This compliant IBR model injects negative sequence current (I₂) during unbalanced faults. Despite the altered control and I₂ injection in the new IBR model, both relays 32T₁ and 32T₂ consistently and accurately identified fault directions in all scenarios (depicted in FIG. 16 and FIG. 17). The robust performance across different IBR types underscores the source-agnostic and control-independent nature of the presently disclosed method.

### C. Sensitivity of the Method to Line Parameters

The presently disclosed method relies on known line parameters to compute A quantities—Aₐ, A_{b} and A_{c} as shown in (19). From (13), it is clear that the sign of dy/dt depends only on ϕₐ, —the phase angle between vs and A. The variation of ϕₐ with the errors in line parameters and its impact on the accuracy of the method are now documented.

Errors in estimating resistive parameters of transmission lines exceed those in inductive parameters [28]. Considering typical range of errors as described in [28] and [29] and accounting for additional error margins due to line transposition imperfections [30], the resistance per km of the transmission line is varied up to 20% and inductance up to 8% of the original values. For a specific scenario-AG fault, 10Ω fault resistance, 60 km from bus 1 on line 1-2 in the test system of FIG. 8(a), the maximum errors in ϕₐ, remain statistically insignificant (3° for variation in resistance and 1° for inductance) compared to the actual value of 25°, preserving the sign of dy/dt.

This is verified by repeating the tests described in Section IV-A applying the worst-case errors in line parameters. Even at maximum variations in ϕₐ, both 32T₁ and 32T₂ relays consistently operate accurately across all scenarios, affirming the presently disclosed method's robustness against changes in line parameters.

### D. Assessment of the Presently Disclosed Method Under CVT Transients and Presence of Strong Source

To assess the robustness of the presently disclosed method, extensive testing is conducted using the relays in FIG. 8(a) with inputs derived from capacitor voltage transformers (CVTs) and current transformers (CTs). Models provided by PSCAD are used for both CVTs and CTs that use the magnetization characteristics of transformers based on [31]. Despite the introduction of transients in the measurement by CVTs, the directionality of the presently disclosed method remains unaffected. This robust performance underscores the method's resilience in practical scenarios, further validating its reliability and applicability in field.

Furthermore, the presently disclosed method has also been successfully tested for very strong systems by replacing the source SS1 in FIG. 8(a) with an equivalent infinite bus model of the source. Although the voltages measured by the relay during fault for a strong system show very little variations, the currents change according to the physics of the fault. This enables the relay to detect faults based on the magnitude of the 120 Hz component. Referring to block diagram in FIG. 7, the relay determines the source type as “strong” as the voltages during faults do not drop below the 0.95 pu threshold set in the source type selection logic. As a result, current based directional element selection logic is selected, which enables the selection of the correct relay element and the relay 32T₁ and 32T₂ accurately determine the direction to fault. Therefore, with the introduction of a parallel current-based directional element selection logic, without any changes to the relay's fundamental operating principle, the presently disclosed relay shows robust performance in presence of strong sources. This further strengthens the argument that the presently disclosed method is source-agnostic.

### E. Application of the Presently Disclosed Method in a Distribution System

The presently disclosed method is further validated using the IEEE 13 bus test feeder, as described in Section III-C. Faults are simulated at three locations: 100 ft, 500 ft and 900 ft from bus 680 in the 1000 ft long line (FIG. 10) to test the direction seen by both the relays—32T₁ and 32T₂—in both grid-connected and islanded modes of operation. Fault resistances up to 5Ω for ground faults and up to 2Ω for phase faults are considered. Higher fault resistances result in fault currents similar to load currents, even for grid-connected mode. This causes the faulted phase voltages to be indistinguishable from the healthy phase voltages. By definition, these are high impedance faults [32] and require special attention; this disclosure does not consider such faults.

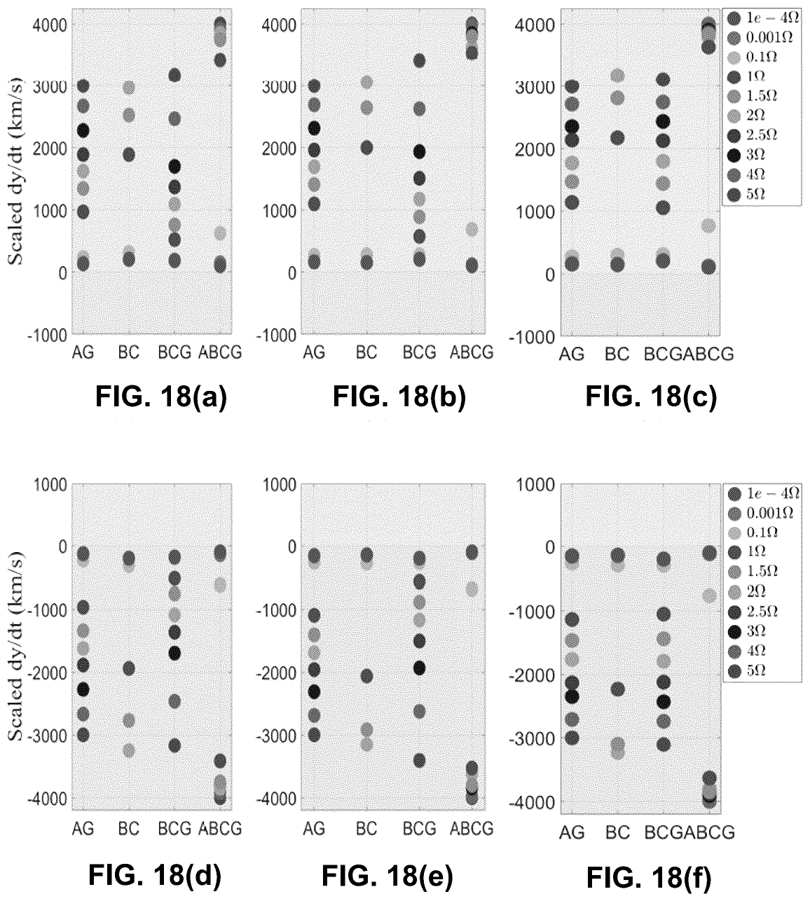

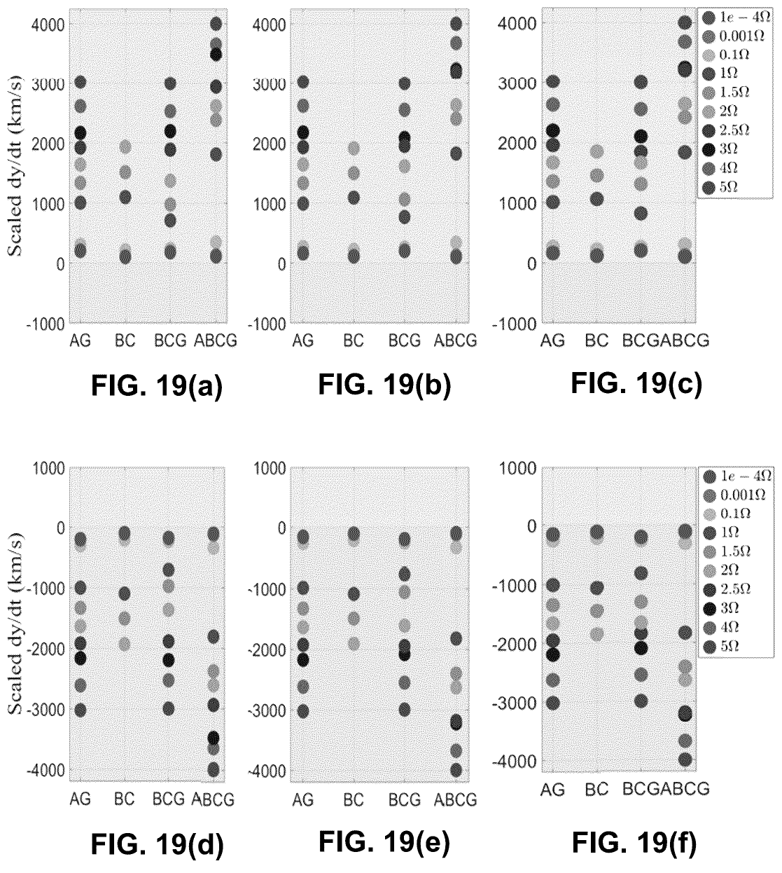

The results for all tested fault scenarios are illustrated in FIG. 18 (grid connected mode) and in FIG. 19 (islanded mode). In particular, FIGS. 18(a), 18(b), 18(c), 18(d), 18(e), and 18(f) graphically represent scaled values of dy/dt calculated by 32T₁ for faults at 100 ft (FIG. 18(a)), 32T₁ for faults at 500 ft (FIG. 18(b)), 32T₁ for faults at 900 ft (FIG. 18(c)), 32T₂ for faults at 100 ft (FIG. 18(d)), 32T₂ for faults at 500 ft (FIG. 18(e)), and 32T₂ for faults at 900 ft (FIG. 18(f)), respectively, on the line in grid connected mode of operation, while FIGS. 19(a), 19(b), 19(c), 19(d), 19(e), and 19(f) graphically represent scaled values of dy/dt calculated by 32T₁ for faults at 100 ft (FIG. 19(a)), 32T₁ for faults at 500 ft (FIG. 19(b)), 32T₁ for faults at 900 ft (FIG. 19(c)), 32T₂ for faults at 100 ft (FIG. 19(d)), 32T₂ for faults at 500 ft (FIG. 19(e)), and 32T₂ for faults at 900 ft (FIG. 19(f)), respectively, on the line in islanded mode of operation;

Both relays correctly identify the fault direction for all faults, even when the fault is as close as 100 ft from the relay, despite the system's inherent unbalanced characteristics. This robustness can be attributed to the method's formulation, which incorporates system unbalance and ensures its general applicability. Furthermore, the relay's accuracy remains unaffected by the system's mode of operation, including islanded conditions with 100% IBR penetration. These results convincingly establish that the presently disclosed relay is not only source-agnostic but also independent of various network topologies.

### F. Security of the Presently Disclosed Method

The presently disclosed method is rigorously tested against non-fault events such as capacitor switching and motor starting.

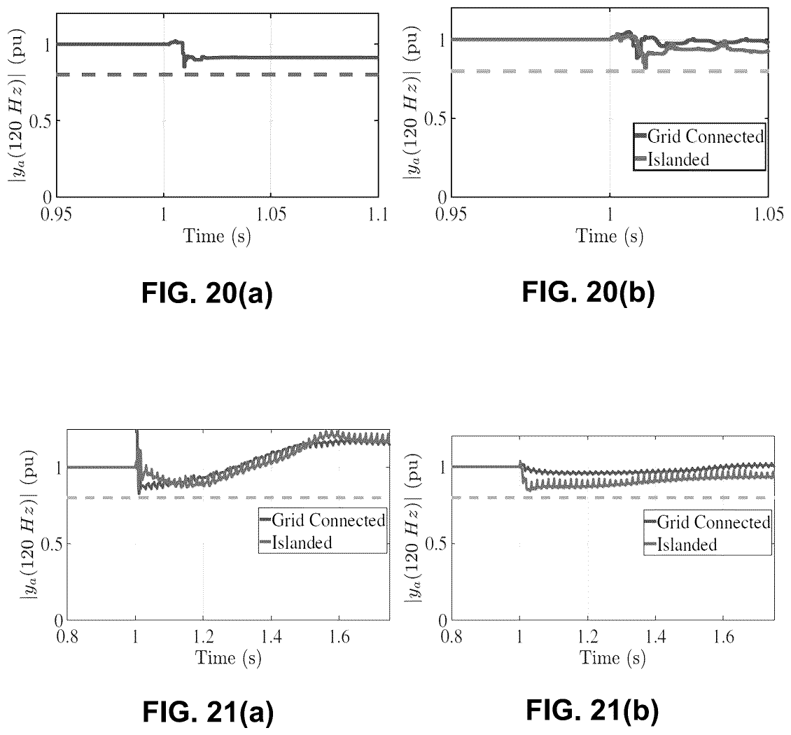

1) Capacitor Switching: The presently disclosed method is tested for capacitor bank switching in both transmission and distribution systems. A 50 MVAR capacitor bank is placed at bus 1 for the high-voltage transmission system (FIG. 8(a)), and a 500 kVAR capacitor bank is added at node 680 for the distribution system (FIG. 10). The Capacitor banks are switched using breakers. Switching events cause a measurable dip in the 120 Hz component of yₐ as depicted in FIGS. 20(a) and 20(b) (switching occurs at t=1 s). However, the magnitude remains above the 0.8 pu threshold, although for a short time coming close to it. The dip is maximum for the distribution system in islanded mode (the mode that produces largest voltage dip for any disturbance due to limited fault currents). In particular, FIGS. 20(a) and 20(b) graphically illustrate the magnitude of the 120 Hz component of yₐ measured by the relay 32T₁ during capacitor bank switching in an exemplary 230 kV transmission system (FIG. 20(a)), and in an exemplary IEEE 13-bus test feeder (FIG. 20(b), respectively.

2) Motor Starting: The presently disclosed method is tested for motor starting using a 300 HP induction motor connected to the IEEE 13 bus test feeder (FIG. 10) through a 300 KVA, 4.16 kV/0.48 kV transformer. The motor is initially connected to bus 680 and later to bus 671. The magnitudes of 120 Hz component of yₐ measured by the relay 32T₁ are depicted in FIGS. 21(a) and 21(b). In particular, FIGS. 21(a) and 21(b) graphically illustrate the magnitude of the 120 Hz component of yₐ measured by the relay 32T₁ when the motor starts at bus 680 (FIG. 21(a)), and bus 671 (FIG. 21(b)), in the exemplary IEEE 13 bus test feeder. The magnitudes remain consistently above the 0.8 pu threshold irrespective of the motor starting location and the mode of operation, restraining the operation of the relay. Moreover, large motors are commonly equipped with power-electronics based soft starters, further mitigating the risks of relay misoperations.

It should be emphasized that for the most severe cases of motor starting and capacitor switching, although the 120 Hz component goes near threshold, it remains at the low value for a small time (0.6 cycles for capacitor switching and 0.7 cycles for motor starting). Since the relay requires the value to be lower than the threshold until the time a trip command is generated (notice how the TRIP command is generated in FIG. 7), even if the threshold is violated for a short time, the relay will perform securely. It should be mentioned here that for all the simulations performed in this disclosure, the operating time of the relay varied between 1.5-2.25 cycles.

### G. Comparison of the Presently Disclosed Method Against Directional Elements Used in Commercial Relays

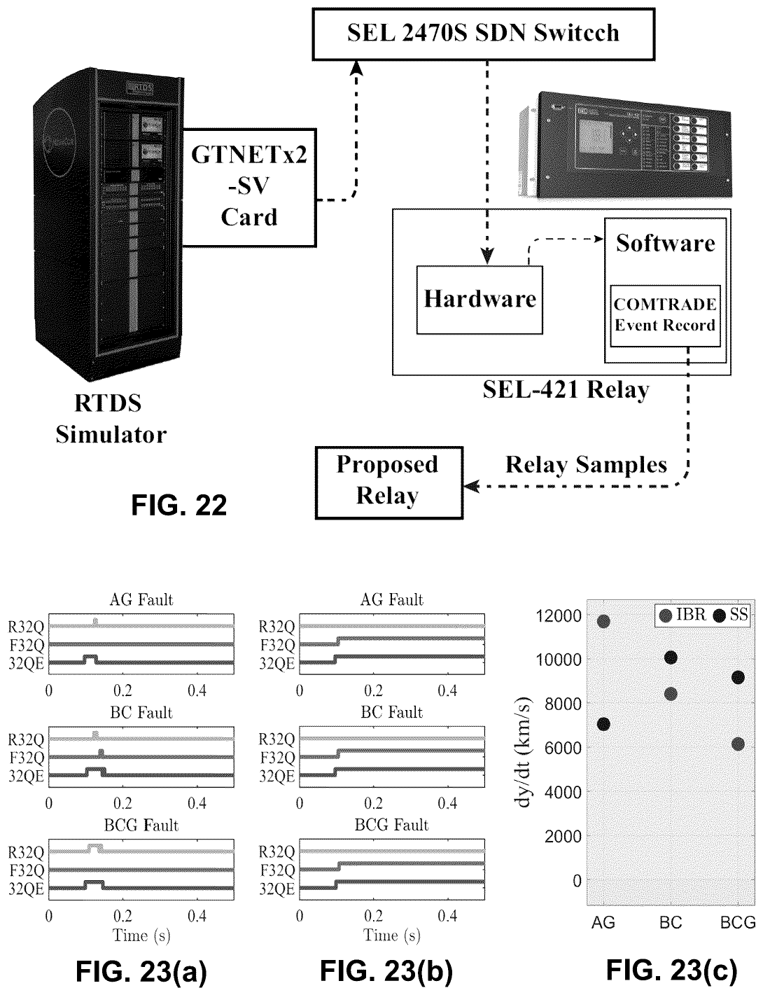

The presently disclosed relay is tested against the widely-used 32Q directional element in commercial relays. The test setup is as shown in FIG. 22. In particular, FIG. 22 schematically represents an exemplary presently disclosed test setup with presently disclosed hardware relay and RTDS (Real Time Digital Simulator) technology, a real-time simulator applied for power systems providing power systems simulation technology. The test systems shown in FIGS. 8(a) and 8(b) are simulated in RTDS; with the relays 32T₁ and 32T₂ replaced by hardware directional relays 32Q1 and 32Q2 (in SEL 421 relays), respectively. Voltage and current measurements are acquired from RTDS and transmitted to the hardware relays using sampled values (SV) communication protocol via the GTNET×2 card. Subsequently, the hardware relays perform their calculation and decision-making.

To assess the efficacy of the presently disclosed method, digital samples recorded by the hardware relays during the events are extracted and fed to the presently disclosed relay algorithm. Since the 32Q element is operative on negative sequence components, only unbalanced faults are used for the testing. Faults are created at 75 km from bus 1 with 10Ω fault resistance.

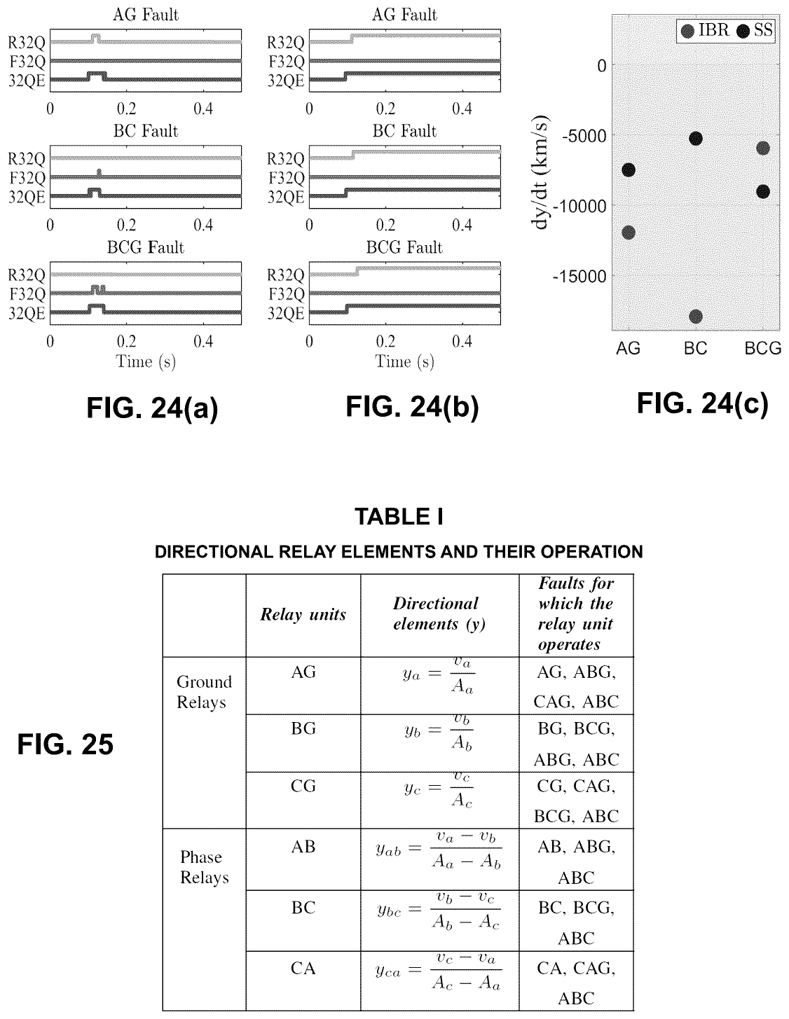

1) Performance of 32Q Element in Presence of IBR: The performance of 32Q directional elements within the SEL-421 relays when fed by IBR is shown in FIG. 23(a) for relay 32Q₁ and in FIG. 24(a) for relay 32Q₂, highlighting their unreliable and erratic behavior. In particular, FIGS. 23(a), 23(b), and 23(c) graphically illustrate directions asserted by 32Q₁ directional element when fed by an IBR (FIG. 23(a)), by 32Q₁ directional element when fed by an SS (FIG. 23(b)), and by the presently disclosed relay technology using the samples from 32Q₁(FIG. 23(c)), while FIGS. 24(a), 24(b), and 24(c) graphically illustrate directions asserted by 32Q₂ directional element when fed by an IBR (FIG. 24(a)), by 32Q₂ directional element when fed by an SS (FIG. 24(b)), and by the presently disclosed relay technology using the samples from 32Q₂ FIG. 24(c)). Throughout the fault period (fault starts at t=0.1 s), except for a brief initial period, the 32Q elements remain disabled. The 32QE (32Q Enable) signal confirms this behavior, which is only enabled when the ratio of negative sequence current (12) to positive sequence current (11) exceeds the set threshold (a2) defined in the relay's settings [33]. Considering the negative sequence current blocking scheme in the inverter control, the a2 setting is set to the minimum possible value of 0.02. Even during the brief period when the 32Q1 is enabled, it misidentifies forward faults as reverse (R32Q is triggered for AG and BCG faults) or fails to discriminate the fault direction (both R32Q and F32Q are triggered for BC fault). Similar misoperation is seen for relay 32Q2 (FIG. 24(a)), where it misidentifies reverse faults as forward (F32Q is triggered for BC and BCG faults). This misoperation is attributed to the 32Q element's reliance on the apparent negative sequence impedance (Z2=V2 I2) for fault direction, which is disrupted by inverter controls altering the output power factor.

2) Performance of 32Q Element With SS: In contrast, when the SEL-421 relays are fed by an SS, the 32QE signal is consistently triggered with the correct fault direction identified throughout the entire fault duration. Forward 32Q (F32Q) and Reverse 32Q (R32Q) elements are correctly triggered for 32Q₁ and 32Q₂, respectively (FIG. 23(b) and FIG. 24(b)).

3) Performance of the Presently Disclosed Method: The presently disclosed relay, when fed with the same samples as used by the 32Q directional elements in SEL-421 relays, accurately determines the fault direction. This accuracy is observed in the positive values of dy/dt calculated using the samples from 32Q₁ element and negative values of dy/dt calculated using the samples from 32Q₂ element, as depicted in FIGS. 23(c) and 24(c), respectively, for all faults, regardless of the source feeding the relay.

Similar results are obtained for other test cases with faults at varying locations and varying fault resistances. These results not only showcase the superiority of the presently disclosed scheme over the widely used directional method in commercial relays but also reinforce the credibility of the presently disclosed method for implementation as a hardware relay in the real world.

### V. CONCLUSION

This disclosure presents a novel and comprehensive directional relay formulated in time domain using generalized differential equations that capture the fundamental physics of faults. This approach makes the relay source-agnostic with 100% accuracy for lines of any length and unbalance, is immune to decaying dc offset, prefault currents and most importantly eliminates the need for complex polarization techniques. Rigorous validation of the presently disclosed theory and claims is conducted through extensive PSCAD/EMTDC simulations, accurately emulating the behavior of commercial inverters during fault scenarios. Furthermore, real-time HIL testing against a commercial 32Q directional element on the RTDS platform demonstrates the superior performance of the presently disclosed relay in the presence of IBRs. Remarkably, this performance is documented at sampling rates as low as 24 spc, establishing it as a ready practical solution for the directional elements in existing numerical relays. All faults are detected between 1.5 to 2.25 cycles, making this relay ideal even for Zone 1 operation of distance relays. This is significant because Standard IEEE 2800-2022 that requires inverters to output negative sequence currents during unbalanced faults, allows 3 cycles for the current to be established, making commercial relays unreliable in that period.

This written description uses examples to disclose the presently disclosed subject matter, including the best mode, and also to enable any person skilled in the art to practice the presently disclosed subject matter, including making and using any devices or systems and performing any incorporated methods. The patentable scope of the presently disclosed subject matter is defined by the claims, and may include other examples that occur to those skilled in the art. Such other examples are intended to be within the scope of the claims if they include structural and/or step elements that do not differ from the literal language of the claims, or if they include equivalent structural and/or elements with insubstantial differences from the literal languages of the claims. In any event, while certain embodiments of the disclosed subject matter have been described using specific terms, such description is for illustrative purposes only, and it is to be understood that changes and variations may be made without departing from the spirit or scope of the subject matter. Also, for purposes of the present disclosure, the terms “a” or “an” entity or object refers to one or more of such entity or object. Accordingly, the terms “a”, “an”, “one or more,” and “at least one” can be used interchangeably herein.

### REFERENCES

[1] S. Khalili and C. Breyer, “Review on 100% renewable energy system analyses—a bibliometric perspective,” IEEE Access, vol. 10, pp. 125 792-125 834, 2022.
[2] M. J. Reno, S. Brahma, A. Bidram, and M. E. Ropp, “Influence of inverter-based resources on microgrid protection: Part 1: Microgrids in radial distribution systems,” IEEE Power and Energy Magazine, vol. 19, no. 3, pp. 36-46, 2021.
[3] G. Kou, J. Jordan, B. Cockerham, R. Patterson, and P. VanSant, “Negative-sequence current injection of transmission solar farms,” IEEE Transactions on Power Delivery, vol. 35, no. 6, pp. 2740-2743, 2020.
[4] IEEE PES Industry Technical Support Task Force and IEEE/NERC Task Force on Short-Circuit and System Performance Impact of Inverter Based Generation, “Impact of inverter based generation on bulk power system dynamics and short-circuit performance,” Tech. Rep. PES-TR68, July 2018.
[5] R. Chowdhury and N. Fischer, “Transmission line protection for systems with inverter-based resources-part I: Problems,” IEEE Transactions on Power Delivery, vol. 36, no. 4, pp. 2416-2425, 2021.
[6] A. Haddadi, M. Zhao, I. Kocar, U. Karaagac, K. W. Chan, and E. Farantatos, “Impact of inverter-based resources on negative sequence quantities-based protection elements,” IEEE Transactions on Power Delivery, vol. 36, no. 1, pp. 289-298, 2021.
[7] Y. Fang, K. Jia, Z. Yang, Y. Li, and T. Bi, “Impact of inverter-interfaced renewable energy generators on distance protection and an improved scheme,” IEEE Transactions on Industrial Electronics, vol. 66, no. 9, pp. 7078-7088, 2019.
[8] M. Nagpal and C. Henville, “Impact of power-electronic sources on transmission line ground fault protection,” IEEE Transactions on Power Delivery, vol. 33, no. 1, pp. 62-70, 2018.
[9] B. Chen, A. Shrestha, F. A. Ituzaro, and N. Fischer, “Addressing protection challenges associated with type 3 and type 4 wind turbine generators,” in 2015 68th Annual Conference for Protective Relay Engineers, 2015, pp. 335-344.
[10] J. Roberts and A. Guzm'an, “Directional element design and evaluation,” in 49th Annual Georgia Tech Protective Relaying Conference. Schweitzer Engineering Laboratories, Inc., May 1995.
[11] A. Banaiemoqadam, A. Hooshyar, and M. A. Azzouz, “A comprehensive dual current control scheme for inverter-based resources to enable correct operation of protective relays,” IEEE Transactions on Power Delivery, pp. 1-1, 2020.
[12] A. Hooshyar and R. Iravani, “A new directional element for microgrid protection,” IEEE Transactions on Smart Grid, vol. 9, no. 6, pp. 6862-6876, 2018.
[13] Z. Yang, Z. Liu, Q. Zhang, Z. Chen, J. d. J. Chavez, and M. Popov, “A control method for converter-interfaced sources to improve operation of directional protection elements,” IEEE Transactions on Power Delivery, vol. 38, no. 1, pp. 642-654, 2023.
[14] R. Chowdhury and N. Fischer, “Transmission line protection for systems with inverter-based resources-part II: Solutions,” IEEE Transactions on Power Delivery, vol. 36, no. 4, pp. 2426-2433, 2021.
[15] P. Adhikari, S. Brahma, and P. H. Gadde, “Addressing the performance of distance relays in presence of inverter based resources,” in 2021 North American Power Symposium (NAPS), 2021, pp. 1-6.
[16] B. Brusilowicz and N. N. Schulz, “Polarizing voltage generating method for distance and directional protection elements,” IEEE Transactions on Power Delivery, vol. 36, no. 1, pp. 74-83, 2021.
[17] F. Namdari and M. Salehi, “High-speed protection scheme based on initial current traveling wave for transmission lines employing mathematical morphology,” IEEE Transactions on Power Delivery, vol. 32, no. 1, pp. 246-253, 2017.
[18] P. Adhikari, S. Brahma, and P. H. Gadde, “Source-agnostic time-domain distance relay,” IEEE Transactions on Power Delivery, vol. 37, no. 5, pp. 3620-3629, 2022.
[19] P. Mishra, A. K. Pradhan, and P. Bajpai, “Time-domain directional relaying using only fault current for distribution system with pv plant,” IEEE Transactions on Power Delivery, vol. 37, no. 4, pp. 2867-2874, 2022.
[20] “IEEE guide for the parameter measurement of ac transmission lines,” IEEE Std 1870-2019, pp. 1-99, 2019.
[21] P. H. Gadde and S. Brahma, “Realistic microgrid test bed for protection and resiliency studies,” in 2019 North American Power Symposium (NAPS), 2019, pp. 1-6.
[22] “Modification of commercial fault calculation program for wind turbine generators,” IEEE Power & Energy Society, Report PES-TR78, 2020.
[23] EPRI, “Short-circuit phasor models of converter based renewable energy resources for fault studies,” EPRI, Palo Alto, CA, Tech. Rep. 3002010936, 2017.
[24] W. H. Kersting, “Radial distribution test feeders,” in 2001 IEEE Power Engineering Society Winter Meeting. Conference Proceedings (Cat. No. 01CH37194), vol. 2, 2001, pp. 908-912 vol. 2.
[25] P. H. Gadde and S. Brahma, “Comparison of PR and PI controllers for inverter control in an unbalanced microgrid,” in 2020 North American Power Symposium (NAPS), 2020, pp. 1-6.
[26] C. Henville and R. Chowdhury, “Coordination of resistive reach of phase and ground distance elements,” in Proceedings of the Western Protective Relay Conference. Spokane, Washington, USA: Henville Consulting Inc. and Schweitzer Engineering Laboratories, Inc., 2021.
[27] EPRI, “PRE-SW: Generic photovoltaic inverter model in an electromagnetic transients simulator for transmission connected plants (PVMODEMT-IBR) v1.0 beta,” EPRI, Tech. Rep., 2023. [Online]. Available: https://www.epri.com/research/products/000000003002025889
[28] J. Fu, G. Song, and B. De Schutter, “Influence of measurement uncertainty on parameter estimation and fault location for transmission lines,” IEEE Transactions on Automation Science and Engineering, vol. 18, no. 1, pp. 337-345, 2021.
[29] Vlahinic, Sasa and Frankovic, Dubravko and Urovic, Marijana Zivic and Stojkovic, Nino, “Measurement uncertainty evaluation of transmission line parameters,” IEEE Transactions on Instrumentation and Measurement, vol. 70, pp. 1-7, 2021.
[30] B. Kasztenny, “Settings considerations for distance elements in line protection applications,” in Proceedings of the 74th Annual Conference for Protective Relay Engineers, College Station, TX, March 2021.
[31] J. R. Lucas, “Representation of magnetization curves over a wide region using a non-integer power series,” International Journal of Electrical Engineering Education, vol. 25, pp. 335-340.
[32] PSRC Working Group D15, “High impedance fault detection technology,” PSRC, Tech. Rep., 1996. [Online]. Available: https://www.pes-psrc.org/kb/report/083.pdf
[33] Schweitzer Engineering Laboratories, Inc., SEL-421-4,-5 Protection, Automation, and Control System Instruction Manual, Schweitzer Engineering Laboratories, Inc., 2022. [Online]. Available: https://selinc.com/api/download/116330/
[34] EIA. Annual Energy Outlook 2021. Tech. rep. U.S. Energy Information Administration, February 2021.url: https://www.eia.gov/outlooks/aeo/

What is claimed is:

1. Methodology for operating a source-agnostic time-domain-based directional relay for use in a power grid, comprising:
associating a relay with or without having one or more inverter-based resources (IBRs) providing power to the power grid;
acquiring measurement data comprising filtered instantaneous time-domain values of voltage and current measurements vs(t) and is(t) taken from the power grid at a low sampling rate; and
determining the direction of current in the relay without converting the time domain samples to phasors at operating frequency of power systems.

2. Methodology according to claim 1, wherein the voltage and current measurements vs(t) and is(t) are obtained at the sending end of the associated power line.

3. Methodology according to claim 2, wherein vf/A is a periodic signal at 120 Hz frequency, where vf is the voltage at the fault point and A represents the voltage drop in the line section per unit length.

4. Methodology according to claim 3, wherein the relay has a plurality of respective directional elements, and the methodology further comprises determining fault detection at the relay, including calculation of the phasor magnitude of the second harmonic component of distance calculations using Discrete Fourier Transform (DFT) for each directional element of the relay.

5. Methodology according to claim 4, wherein the methodology further comprises selecting the correct directional element associated with determined fault, including determining different fault types based on operating relay units comprising a plurality of ground relay units and line relay units.

6. Methodology according to claim 5, wherein ground relay units are operative for line-to-ground (LG), doubleline-to-ground (LLG), and three-phase (3 ph) faults, while line relay units are operative for line-to-line (LL) and 3 ph faults.

7. Methodology according to claim 5, further comprising determining whether a fault signature is associated with a strong or a weak source.

8. Methodology according to claim 4, further comprising determining the fault direction by calculating the derivative dy/dt at the peak of quantity A for each directional element of the relay, with the sign of the calculated dy/dt determining the direction of the fault.

9. Methodology according to claim 7, determining a fault signature is associated with a strong source if a fault is detected and the measurement data shows that voltage measurements stay at or above a preset threshold.

10. A source-agnostic time-domain-based directional relay for use in a power grid, comprising:
a relay having a plurality of respective directional elements, associated with a power grid with or without having one or more inverter-based resource (IBR) providing power to the power grid;
measurement sensors acquiring data that are filtered to yield instantaneous time-domain values of voltage and current measurements vs(t) and is(t) taken from the power grid at a low sampling rate; and
one or more sensor processors programmed for determining the direction of current in the relay without converting the time-domain values to phasors at operating frequency of power systems.

11. The source-agnostic time-domain-based directional relay according to claim 10, wherein the voltage and current measurements vs(t) and is(t) are obtained at the sending end of the associated power line.

12. The source-agnostic time-domain-based directional relay according to claim 11, wherein vf/A is a periodic signal at 120 Hz frequency, and where vf is the voltage at the fault point and A represents the voltage drop in the line section per unit length.

13. The source-agnostic time-domain-based directional relay according to claim 12, wherein the one or more sensor processors are further programmed for determining fault detection at the relay, including calculation of the phasor magnitude of the second harmonic component of distance calculations using Discrete Fourier Transform (DFT) for each directional element of the relay.

14. The source-agnostic time-domain-based directional relay according to claim 13, wherein the one or more sensor processors are further programmed for selecting the correct directional element associated with determined fault, including determining different fault types based on operating relay units comprising a plurality of ground relay units and line relay units.

15. The source-agnostic time-domain-based directional relay according to claim 14, wherein the ground relay units are operative for line-to-ground (LG), doubleline-to-ground (LLG), and three-phase (3 ph) faults, while the line relay units are operative for line-to-line (LL) and 3 ph faults.

16. The source-agnostic time-domain-based directional relay according to claim 14, wherein the one or more sensor processors are further programmed for determining whether a fault signature is associated with a strong or a weak source.

17. The source-agnostic time-domain-based directional relay according to claim 13, wherein the one or more sensor processors are further programmed for determining the fault direction by calculating the derivative dy/dt at the peak of quantity A for each directional element of the relay, with the sign of the calculated dy/dt determining the direction of the fault.

18. The source-agnostic time-domain-based directional relay according to claim 16, wherein the one or more sensor processors are further programmed for determining a fault signature is associated with a strong source if a fault is detected and the measurement data shows that voltage measurements stay at or above a preset threshold.
